(19) United States
(12) Patent Application Publication
(10) Pub. No.: US 2009/0157340 A1
(43) Pub. Date: Jun. 18, 2009

(54) Method and system for yield enhancement

(75) Inventors: Anand Gopalan, San Mateo, CA (US); Yoshinori Nishi, San Jose, CA (US)

Correspondence Address: OLIFF & BERRIDGE, PLC, P.O. BOX 320850, ALEXANDRIA, VA, 22320-4850, US

(73) Assignee: KAWASAKI MICROELECTRONICS U.S.A., INC., SAN JOSE, CA (US)

(21) Appl. No.: 12/000,761

(22) Filed: Dec. 17, 2007

(51) Int. Cl. G01D 18/00; G01R 31/00

(52) U.S. Cl. 702/85; 702/117

(57) ABSTRACT

Aspects of the disclosure provide a method for calibrating a circuit performance. The method can stabilize the circuit performance over time, and maintain the circuit performance substantially in a specification independent of various variation sources. Therefore, chip reliability can be improved and high product yield can be achieved. The method for calibrating the circuit performance can include assigning levels to a set of circuit parameters of a circuit, measuring values of the circuit parameters during operation of the circuit, generating a control signal that corresponds to the measured circuit parameters weighted according to the assigned levels, and adjusting a feedback relationship of a feedback loop circuit of the circuit in a close loop feedback system according to the control signal so as to change the circuit performance.

### BACKGROUND

Semiconductor product yield can be affected by numerous variations, such as process variations and environmental conditions. Process variations can cause device parameters vary from chip to chip. For example, oxidation process variation may cause MOS transistor threshold voltage vary from chip to chip, and poly doping variation may cause poly resistor resistance vary from chip to chip. Further, the device parameter variations may cause circuit performance vary from chip to chip. For example, a gain of an amplifier that includes MOS transistors and poly resistors can depend on the threshold voltage of the MOS transistors and the resistance of the poly resistors. Therefore, the MOS transistor threshold voltage variation and the poly resistor resistance variation can vary the amplifier gain.

In addition, environmental conditions, such as temperature and supply voltage, can change over time during operation. For example, a chip temperature can vary with external temperature and chip power consumption. The supply voltage may vary from one power supply to another power supply, and may vary with current load. The environmental conditions can also vary circuit performance. When a circuit performance varies exceeding specification, the circuit can fail, and product yield can suffer.

### SUMMARY

Aspects of the disclosure provide a method for calibrating a circuit performance. The method can stabilize the circuit performance over time, and maintain the circuit performance substantially in a specification independent of various variation sources. Therefore, chip reliability can be improved and high product yield can be achieved. The method for calibrating the circuit performance can include assigning levels to a set of circuit parameters of a circuit, measuring values of the circuit parameters during operation of the circuit, generating a control signal that corresponds to the measured circuit parameters weighted according to the assigned levels, and adjusting a feedback relationship of a feedback loop of the circuit in a close loop feedback system according to the control signal so as to change the circuit performance.

To assign the levels to the set of circuit parameters of the circuit, the method can further include storing a predefined relationship of the circuit parameters and corresponding levels. Alternatively, the method can include receiving a user-defined relationship of circuit parameters and corresponding levels.

To measure the values of the circuit parameters during operation of the circuit, the method can further include generating a reference signal that is independent of process variations, temperature variation, and supply voltage variation, and measuring the values of the circuit parameters regarding the reference signal. In an embodiment, the reference signal can be generated based on a band-gap reference signal.

Additionally, to measure the values of the circuit parameters during operation of the circuit, the method can include converting the measured values to digital values, and storing the digital values. Furthermore, according to an aspect of the disclosure, the feedback relationship can include a ratio between a circuit adjustment and a measured circuit parameter.

The method for calibrating a circuit performance can also include assigning a level to at least one circuit parameter of a circuit, measuring a value of the at least one circuit parameter during operation of the circuit, generating a control signal that corresponds to the value of the at least one measured circuit parameter weighted according to the assigned level, and adjusting a feedback relationship of a feedback loop of the circuit in a close loop feedback system according to the control signal so as to change the circuit performance.

Aspects of the disclosure can also provide a system for calibrating a circuit performance. The system for calibrating the circuit performance can include a circuit that is configured to have an adjustable parameter that adjusts the circuit performance, a feedback loop circuit that is configured to have a feedback relationship of an adjustment of the adjustable parameter and a measured circuit parameter, and a yield enhancement unit that is configured to assign a level to at least one circuit parameter, measure a value of the at least one circuit parameter during operation of the circuit, generate a control signal that corresponds to the measured at least one circuit parameter weighted according to the assigned level, and adjust the feedback relationship according to the control signal to change the circuit performance.

Additionally, the disclosure can also provide an IC chip having an on-chip system for calibrating a circuit performance. The IC chip can include a circuit that is configured to have an adjustable parameter that adjusts the circuit performance, a feedback loop circuit that is configured to have a feedback relationship of an adjustment of the adjustable parameter and a measured circuit parameter, and a yield enhancement unit that is configured to assign a level to at least one circuit parameter, measure a value of the at least one circuit parameter during operation of the circuit, generate a control signal that corresponds to the measured at least one circuit parameter weighted according to the assigned level, and adjust the feedback relationship according to the control signal to change the circuit performance.

### BRIEF DESCRIPTION OF THE DRAWINGS

Various exemplary embodiments of this disclosure will be described in detail with reference to the following figures, wherein like numerals reference like elements, and wherein:

FIG. 1 shows a block diagram of an exemplary IC chip that can include an on-chip yield enhancement system;

FIG. 2 shows a block diagram of an exemplary circuit architecture utilizing the yield enhancement system to achieve desired circuit performance;

FIG. 3 shows a block diagram of an exemplary yield enhancement system;

FIG. 4 shows another block diagram of an exemplary yield enhancement system;

FIG. 5 shows a diagram of an exemplary finite state machine;

FIG. 6 shows a flow chart outlining an exemplary process for achieving stable and desired circuit performance; and

FIG. 7 shows a diagram of an exemplary multiplexer.

### DETAILED DESCRIPTION OF EMBODIMENTS

In a technique to stabilize circuit performance, a close loop feedback system can be used. The close loop feedback system can sense a circuit parameter, and adjust circuit condition according to the sensed circuit parameter in a continuous manner. The close loop feedback system may target limited sources of variations, and may be unstable.

In another technique, an open loop system can be used. The open loop system can monitor various circuit parameters, such as various process, and environmental conditions, and adjust circuit condition according to the combined monitoring results in a determined manner. However, the open loop system cannot address variations that may happen over time.

Aspects of the disclosure can provide a method that utilizes an on-chip yield enhancement system to monitor various variations and provide control signals to adjust a feedback relationship of a close loop feedback system, so as to stable the circuit performance over time within a desired range.

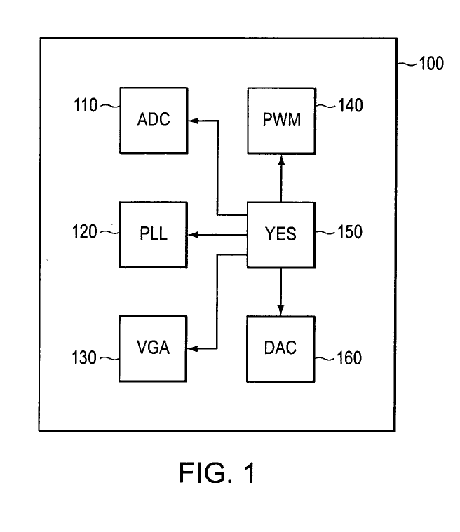

FIG. 1 shows a block diagram of an exemplary IC chip 100 that can include an on-chip yield enhancement system. As shown in FIG. 1, the IC chip 100 can be designed using a system-on-chip (SoC) technology, thus various functional blocks, such as analog to digital converter (ADC) block 110, phase locked loop (PLL) block 120, variable gain amplifier (VGA) block 130, pulse width modulator (PWM) block 140, and digital to analog converter (DAC) block 160, can be integrated in the IC chip 100.

As also shown in FIG. 1, the IC chip 100 can include a yield enhancement system (YES) 150 that can be integrated as part of the IC chip 100. The YES 150 can be coupled with various functional blocks as shown, and can provide control signals to various functional blocks respectively. The control signals can be generated based on various circuit parameters. For example, the control signals can be generated based on device parameters, such as MOS transistor threshold voltage, poly resistor resistance, and the like. Moreover, the control signals can be generated based on environmental parameters, such as temperature, supply voltage, and the like. Further, the control signals can be generated based on performance parameters, such as speed, power consumption, and the like, which may vary with various process and environmental conditions. In addition, the control signals can be generated based on characteristics of individual functional circuit block, and can vary from one circuit block to another. Moreover, the control signals can be generated based on specific applications, and can vary from one application to another. Additionally, the control signals can be generated based on spatial or temporal indexes of the IC chip 100, such as wafer numbers, coordinates and the like.

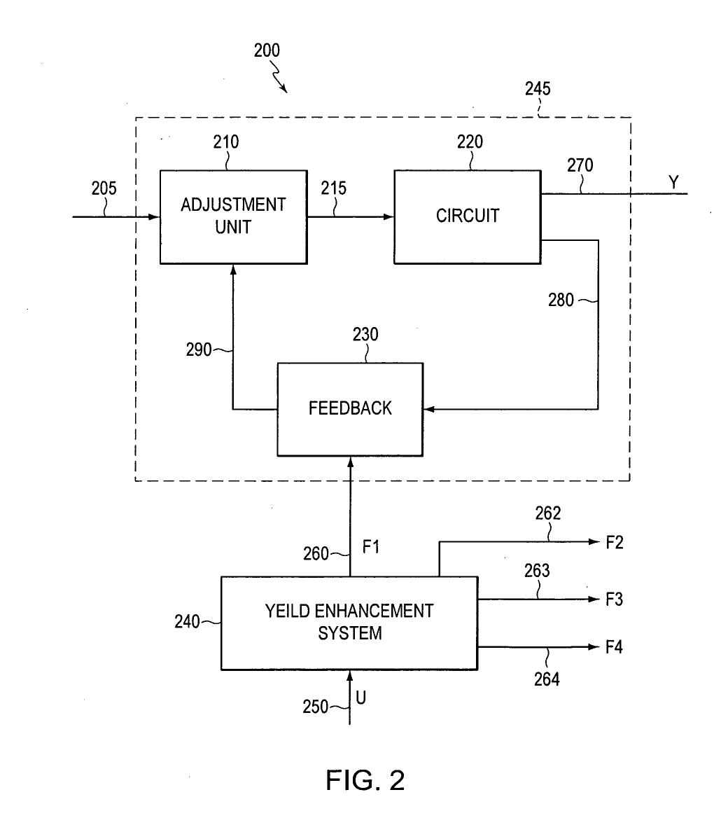

FIG. 2 shows a block diagram of an exemplary circuit architecture 200 utilizing the yield enhancement system to achieve desired circuit performance. The exemplary circuit architecture 200 can include a close loop feedback system 245 and a yield enhancement system 240 coupled as shown. The close loop feedback system 245 can tune a circuit performance 270 by adjusting an adjustable parameter 205 based on a sensed circuit parameter 280. The yield enhancement system 240 can provide a feedback loop control signal 260 to tune the close loop feedback system 245 to achieve the stable and desired circuit performance 270.

The close loop feedback system 245 can include a circuit unit 220, a feedback unit 230, and an adjustment unit 210 coupled as shown. The circuit unit 220 can be a functional block, such as ADC 110, PLL 120, VGA 130, PWM 140, DAC 160, and the like, which can achieve a circuit performance 270. The circuit performance 270 of the circuit unit 220 can be adjusted by modifying the adjustable parameter 205. For example, the circuit unit 220 can be a VGA that can achieve a specific output amplitude. The specific output amplitude, which can be used to measure the VGA performance, can be adjusted by a current provided to an amplifier within the VGA. The current can vary the amplifier gain, and thus result in a change of the specific output amplitude of the VGA.

The adjustment unit 210 can modify the adjustable parameter 205 with an adjustment parameter 290 so as to adjust the circuit performance 270. For example, the adjustment unit 210 can increase or decrease the current provided to the amplifier, therefore, the gain of the amplifier can be adjusted.

The feedback unit 230 can sense the circuit parameter 280, and provide the adjustment parameter 290 to the adjustment unit 210. The adjustment parameter 290 can be determined based on the sensed circuit parameter 280 according to a feedback relationship, such as a constant ratio between the adjustment parameter 290 and the sensed circuit parameter 280. In the example of the VGA, the feedback unit 230 can sense an amplifier power of the VGA, which can indicate the output amplitude. Then the feedback unit 230 can provide a current adjustment to the VGA based on the sensed amplifier power. Then the adjustment unit 210 can adjust the VGA current according to the current adjustment. More specifically, when the sensed amplifier power is larger than a desired value, the feedback unit 230 may provide a negative current adjustment. The negative current adjustment can decrease a gain of the VGA, so as to decrease the output amplitude. Alternatively, when the sense amplifier power is smaller than the desired value, the feedback unit 230 can provide a positive current adjustment. The positive current adjustment can increase the gain of the VGA, so as to increase the output amplitude.

The yield enhancement system 240 can include various monitoring circuits that can monitor various circuit parameters. The yield enhancement system 240 can monitor on-chip semiconductor device parameters, which can vary with the process variations. For example, the yield enhancement system 240 can monitor MOS transistor threshold voltage, which can vary with the gate oxide oxidation process.

Further, the yield enhancement system 240 can monitor environmental parameters during operation. For example, the yield enhancement system 240 can monitor a chip temperature, which can affect circuit performance. The yield enhancement system 240 can utilize a proportional to absolute temperature (PTAT) voltage reference, which can vary with the chip temperature, to monitor the chip temperature variation during operation.

Moreover, the yield enhancement system 240 can monitor performance parameters, such as speed, power consumption, and like. For example, the yield enhancement system 240 can monitor an operational speed, such as ring oscillator frequency, which can be affected by process and environmental conditions, and can affect speed sensitive circuit performance.

Additionally, the yield enhancement system 240 can determine characteristics of the circuit 220. The characteristics can include circuit 220 sensitivities to various monitored circuit parameters, such as sensitivity to MOS transistor threshold voltage, sensitivity to temperature, and the like. The characteristics can also include application specific requirements, such as different specification for different application. The characteristic can also include chip temporal and spatial indexes, such as lot number, wafer number, chip coordinates and the like.

Subsequently, the yield enhancement system 240 can combine the monitored circuit parameters and characteristics of circuit 220 to generate a feedback loop control signal 260, and then provide the feedback loop control signal 260 to reconfigure the close loop feedback system 245. For example, the feedback loop control signal 260 can be used to adjust a relationship of the adjustment parameter 290 and the sensed circuit parameter 280. In an embodiment, the close loop feedback system 245 can have a constant ratio feedback relationship of the adjustment parameter 290 and the sensed the circuit parameter 280. Then the feedback loop control signal 260 can adjust the constant ratio feedback relationship. For example, a new constant ratio can be calculated by multiplying the feedback loop control signal 260 with the old constant ratio. Therefore, when the feedback loop control signal 260 is zero, the constant ratio is zero, the adjustment parameter 290 is zero, and the close loop feedback system 245 can be configured to an open loop circuit. When the feedback loop control signal 260 is 1, the ratio of the adjustment signal 290 and the sensed circuit parameter 280 can be kept. Therefore, the close loop feedback system 245 can be configured to a regular close loop feedback system. When the feedback loop control signal 260 is larger or smaller than 1, the constant ratio of the adjustment signal 290 and the sensed circuit parameter 280 can be modified, the close loop feedback system 245 can make larger or smaller adjustment to the circuit performance 270 comparing to the regular close loop feedback system.

Moreover, the feedback loop control signal 260 can be a continuous signal or a discrete signal. When the feedback loop control signal 260 is a continuous signal, the close loop feedback control system 245 can be continuously adjusted according to the feedback loop control signal 260. When the feedback loop control signal 260 is a discrete signal that is triggered by events, the adjustments to the close loop feedback control system 245 can be triggered by the events. For each circuit unit, the yield enhancement system 240 can generate a corresponding control signal, such as signals F1-F4, based on characteristics of the respective circuit unit.

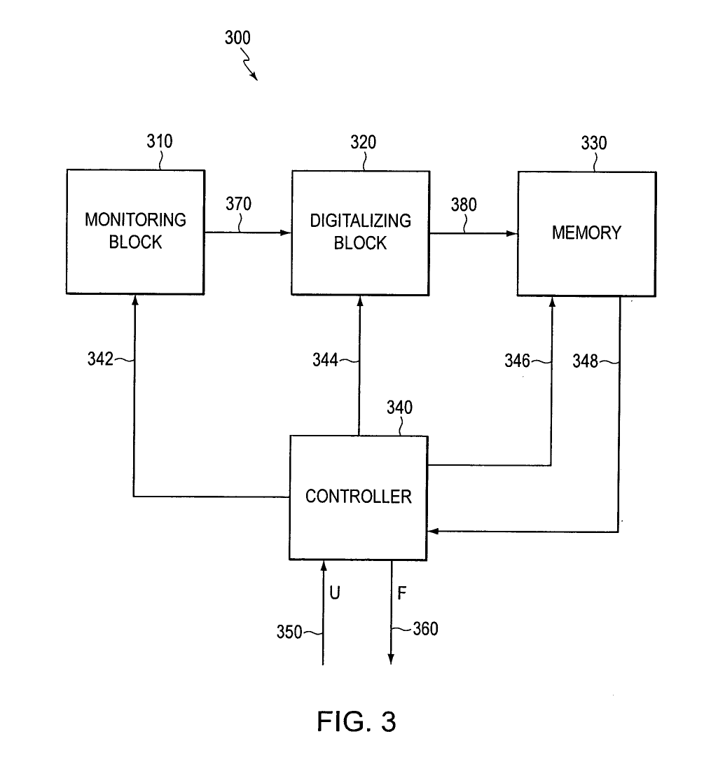

FIG. 3 shows a block diagram of an exemplary yield enhancement system 300. The exemplary yield enhancement system 300 can include a monitoring block 310, a digitalizing block 320, and a memory unit 330 coupled as shown. In addition, the exemplary yield enhancement system 300 can include a controller 340 that can be coupled with the monitoring block 310, the digitalizing block 320 and the memory unit 330. The controller 340 can coordinate components of the yield enhancement system 300.

The monitoring block 310 can monitor various circuit parameters, and can generate a monitoring signal 370 representing a monitored circuit parameter. For example, the monitoring block 310 can generate a voltage signal, whose amplitude can vary with a monitored circuit parameter.

The digitalizing block 320 can convert the monitoring signal 370 into a digital signal 380. The digital signal 380 can be saved in the memory unit 330. The memory unit 330 can save the digital signal 380, and provide a saved digital signal 348 to the controller 340. The controller 340 can provide yield enhancement control signals, such as 342, 344 and 346, to the monitoring block 310, the digitalizing block 320 and the memory unit 330 to coordinate their operation. In addition, the controller 340 can receive a user signal 350. The user signal 350 can include circuit characteristics of a circuit block. The controller 340 can combine the saved digital signals 348 and the user signal 350 to generate a feedback loop control signal 360, and provide the feedback loop control signal 360 to the circuit block. While the exemplary yield enhancement system 300 is shown with the user signal as an input to the yield enhancement system, it should be understood that the user signal 350 can be stored in a memory unit that can be included in the on-chip yield enhancement system.

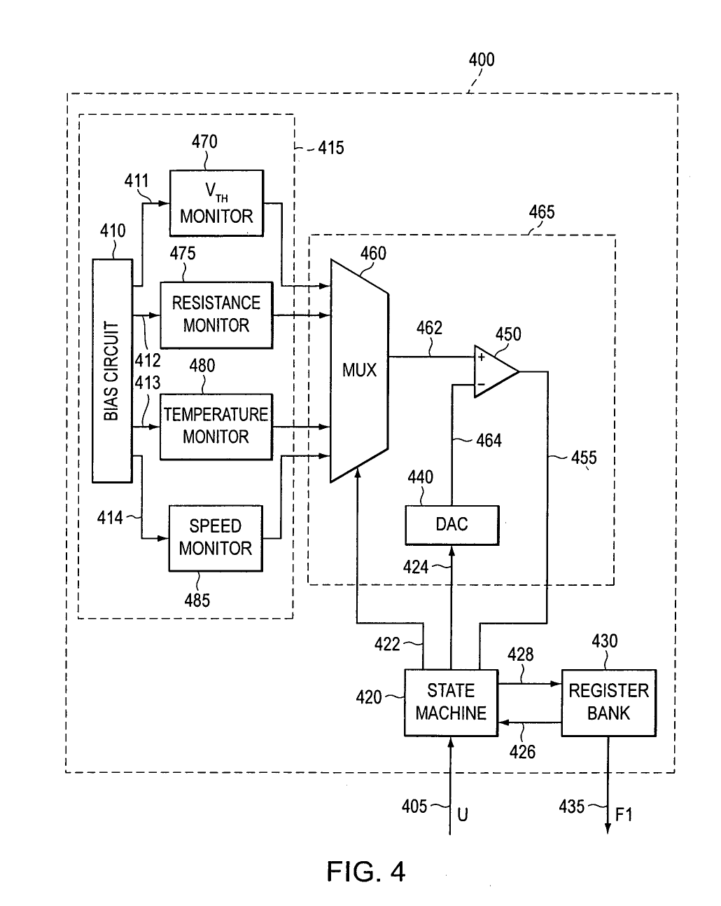

FIG. 4 shows a more detailed block diagram of an exemplary yield enhancement system 400. The exemplary yield enhancement system 400 can include a monitoring block 415, a digitalizing block 465, a memory unit in a form of register bank 430, and a controller in a form of finite state machine 420. The monitoring block 415 can include various monitoring circuits that can generate various monitoring signals. The digitalizing block 465 can convert the various monitoring signals into digital signals. The register bank 430 can save the digital signals. The finite state machine 420 can coordinate operations of the yield enhancement system 400, and can calculate the feedback loop control signals.

The monitoring block 415 can include a bias circuit 410 and various variation monitors, such as MOS threshold voltage monitor 470, poly resistor resistance monitor 475, temperature monitor 480, and circuit speed monitor 485. The bias circuit 410 can generate references 411-414 that can be independent of various variations, such as process variations, temperature and supply voltage variations. For example, the bias circuit 410 can generate voltage and current references based on a band-gap reference, which can be substantially independent of process, temperature and supply voltage variations. The variation independent reference signals can be provided to the variation monitors for reference.

Each of the variation monitors can include a variation sensitive structure that can be sensitive to a variation source. The variation sensitive structure can generate an output signal with reference to the variation independent reference signal, such as 411-414. Therefore, the output signal can be used to monitor the variation source. For example, the MOS threshold voltage monitor 470 can include a diode connected MOS transistor. The diode connected MOS transistor can have a current-voltage characteristic, which is sensitive to MOS transistor threshold voltage, when current is small. Therefore, the diode connected MOS transistor can be driven by a small variation independent current reference 411, thus a drain-source voltage of the diode connected MOS transistor can be used as a variation monitoring signal to monitor the MOS transistor threshold voltage variation.

Generally, the various variation monitoring signals can be analog signals. The various analog variation monitoring signals can be converted into digital signals by the digitalizing block 465. The digital signals can be easily saved and processed to generate the feedback loop control signals.

The exemplary digitalizing block 465 can include a multiplexer 460, a comparator 450 and a digital to analog converter (DAC) 440. The multiplexer 460 can be configured to output an analog variation monitoring signal 462 from the various analog variation monitoring signals connected to its inputs. The DAC 440 can convert a digital number 424, which can be an expectant digital equivalent of the analog variation monitoring signal 462, to an analog signal 464. The comparator 450 can compare the selected analog variation monitoring signal 462 with the converted analog signal 464, and generate a comparison result 455. Depending on the comparison result 455, the expectant digital equivalent number 424 can be controlled by the finite state machine 420 to increase or decrease in order to approach the analog variation monitoring signal 462.

The finite state machine 420 can control the digitalizing block 465 to convert various analog monitoring signals into digital signals, and control the register bank 430 to save the digital signals.

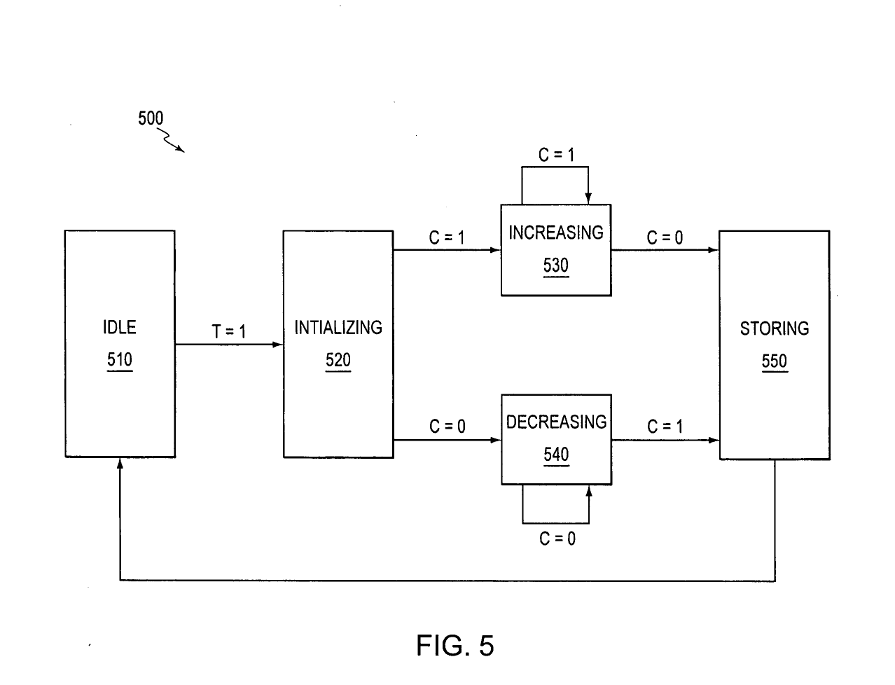

FIG. 5 shows a diagram of an exemplary finite state machine 500 that can control the exemplary yield enhancement system 400 to convert an analog variation monitoring signal into a digital signal, and save the digital signal in the register bank 430. The finite state machine 500 can be embedded as a part of the finite state machine 420, and coupled with the components of the exemplary yield enhancement system 400. The finite state machine 500 can provide a selecting signal 422 to the multiplexer 460. Further, the finite state machine 500 can provide an expectant digital equivalent signal 424 to the digitalizing block 465. Additionally, the finite state machine 500 can provide a digital number 428, which can be equivalent to the analog variation monitoring signal 462, to the register bank 430 for storing. On the other hand, the state machine 500 can receive from the comparator 450 a comparison result 455, which is represented by C in the FIG. 5, to control state transitions of the finite state machine 500.

The finite state machine 500 can include 5 states: idle state 510, initializing state 520, increasing state 530, decreasing state 540, and storing state 550. During the idle state 510, nothing changes, the finite state machine 500 can wait for a trigger signal to begin a conversion process. During the initializing state 520, the finite state machine 500 can control the digitalizing block 465 to initialize. The finite state machine 500 can switch the multiplexer 460 to select an analog monitoring signal 462, and can initialize an expectant digital number 424 to the DAC 440. During the increasing state 530, the finite state machine 500 can increase the expectant digital number 424. During the decreasing state 540, the finite state machine 500 can decrease the expectant digital number 424. During the storing state, the finite state machine 500 can control the register bank 430 to store a digital number 428.

The finite state machine 500 can work in the following configuration. The finite state machine 500 can start at the idle state 510. Then a trigger signal T can trigger the finite state machine 500 transit to the initializing state 520. The trigger signal T can be set by a user instruction, a timer, an out of specification event, and the like.

During the initialization state 520, the finite state machine 500 may send a selecting signal 422 to switch the multiplexer 460 to select an analog monitoring signal 462, and may initialize an expectant digital number 424 that may correspond to the selected analog signal 462. In an embodiment, a relationship of the selecting signal 422 and initial expectant digital number 424 can be stored in a memory medium, such as register bank 430. The finite state machine 500 may search the memory medium for the initial expectant digital number 424 that corresponds to the selecting signal 422.

Then, the expectant digital number 424 can be converted to an expectant analog signal 464 by the DAC 440. The expectant analog signal 464 can be compared to the chosen analog monitoring signal 462 by the comparator 450. The comparator 450 can generate a comparison result 455, which is represented by C in FIG. 5. The comparison result C can control the state transition of the finite state machine 500. For example, when the comparison result C is 1, which means the selected analog monitoring signal 462 is larger than the expectant analog signal 464, the finite state machine 500 can transit from state 520 to state 530 to increase the expectant digital number 424. Subsequently, the increased expectant digital number 424 can be converted to the increased expectant analog signal 464, which can be compared to the analog monitoring signal 462. If the comparison result C is still 1, the finite state machine 500 can keep the state 530, which can continue increasing the expectant digital number 424 until the comparison result C is 0, which can mean that the current expectant digital number 424 is within a close range of the analog signal 462. Then the finite state machine 500 can transit from state 530 to state 550 that the finite state machine 500 can control the register bank 430 to store the current expectant digital number 428 as a digital number that can be equivalent to the analog monitoring signal 462.

On the other hand, when the comparison result C is 0, which means the selected analog monitoring signal 462 is smaller than the expectant analog signal 464, the finite state machine 500 can transit from state 520 to state 540 to decrease the expectant digital number 424. Subsequently, the decreased expectant digital number 424 can be converted to the decreased analog signal 464, which can be compared to the analog signal 462. If the comparison result C is still 0, the finite state machine 500 can keep the state 540, which can continue decreasing the expectant digital number 424 until the comparison result C is 1, which can mean the current expectant digital number 424 is within a close range of the analog signal 462. Then the finite state machine 500 can transit from state 540 to state 550 that the finite state machine 500 can control the register bank 430 to store the current expectant digital number 428 as a digital number that can be equivalent to the analog monitoring signal 462. After storing the current expectant digital number 428, the finite state machine 500 can transit from state 550 to state 510 to stay idle waiting for the next trigger signal.

The finite state machine 500 may repeat the above process to switch the multiplexer 460 to select other analog monitoring signals, convert the other analog monitoring signals into digital numbers, and save the digital numbers into the register bank 430. It should be understood that the above process can be improved by various algorithms to converge faster to the final digital numbers.

In addition, the finite state machine 420 can receive a user signal 405. The user signal 405 can include a relationship of monitored circuit parameters and levels of control. The levels of control can be decided according to circuit sensitivities to the monitored circuit parameters, specific application requirements, chip temporal and spatial indexes, and the like. The finite state machine 420 can then determine a feedback loop control signal combining the saved digital numbers and corresponding levels of control. The feedback loop control signal can also be saved in the register bank 430, and provided to the corresponding circuit block.

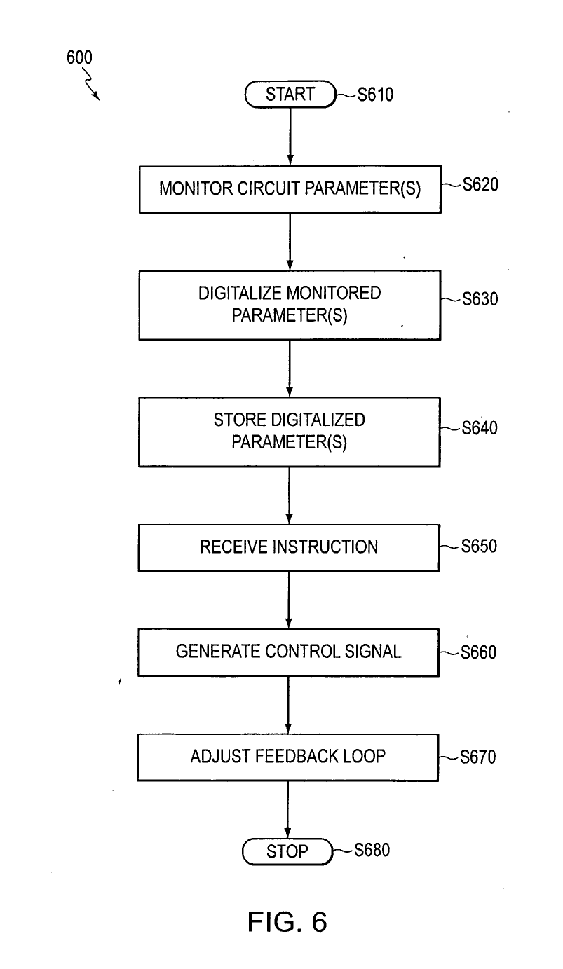

FIG. 6 shows a flow chart outlining an exemplary process 600 for utilizing yield enhancement system to tune a feedback control loop of a circuit in order to achieve stable and desired circuit performance. The process starts at step S610, and proceeds to step S620, where a monitoring mechanism, such as a monitoring circuit in the monitoring block 415, can generate a monitoring signal that can represent a circuit parameter, such as MOS transistor threshold voltage, MOS transistor transconductance, poly resistor resistance, chip temperature, supply voltage, and the like.

Then, the process proceeds to step S630, where a digitalizing mechanism, such as the digitalizing block 465, can convert the monitoring signal, which can be an analog signal, to a digital number. The process then proceeds to step S640, where the digital number can be stored in a memory medium, such as register bank 430. The step S620-S640 can be repeated for various circuit parameters. Therefore, the memory medium can store various digital numbers that correspond to various circuit parameters.

Subsequently, the process proceeds to step S650, where the yield enhancement system can receive an instruction signal. In an embodiment, the instruction signal can be stored in a memory medium within the yield enhancement system. The instruction signal can include a relationship of circuit parameters and corresponding levels of control. Then the process proceeds to step S660, where the yield enhancement system can generate a feedback loop control signal, which can combine the monitoring signals and corresponding levels of control according to the relationship of circuit parameters and corresponding levels of control.

The process then proceeds to step S670, where the yield enhancement system can use the feedback loop control signal to adjust the close loop feedback control system of the circuit. For example, the feedback loop control signal 260 in FIG. 2 can adjust a ratio of the adjustment signal 290 and sensed circuit parameter 280. Then, the process proceeds to step S680, and terminates.

It should be understood that the exemplary components of the yield enhancement system, such as ADC, DAC, multiplexer, finite state machine, and register bank, can be implemented by other existing or later developed circuit techniques. For example, due to the loose speed requirement of the yield enhancement system, the multiplexer can be simplified.

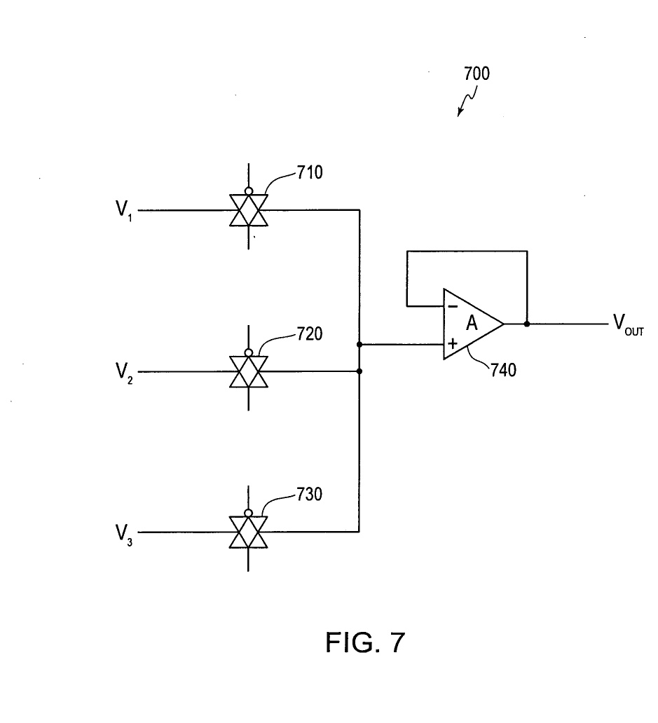

FIG. 7 shows an exemplary simple multiplexer 700. The exemplary multiplexer 700 can include an output buffer or unit gain amplifier 740, and multiple pass gate switches, such as 710-730. Each of the pass gate switches can be controlled to permit an analog monitoring signal V1-V3 to be connected to the unit gain amplifier 740.

While the invention has been described in conjunction with the specific exemplary embodiments thereof, it is evident that many alternatives, modifications, and variations will be apparent to those skilled in the art. Accordingly, exemplary embodiments of the invention as set forth herein are intended to be illustrative, not limiting. There are changes that may be made without departing from the spirit and scope of the invention.

What is claimed is:

1. A method for calibrating a circuit performance, comprising:
assigning levels to a set of circuit parameters of a circuit;
measuring values of the circuit parameters during operation of the circuit;
generating a control signal that corresponds to the measured circuit parameters weighted according to the assigned levels; and
adjusting a feedback relationship of a feedback loop of the circuit in a close loop feedback system according to the control signal so as to change the circuit performance.

2. The method according to claim 1, wherein assigning the levels to the set of circuit parameters of the circuit, further comprises:
storing a predefined relationship of the circuit parameters and corresponding levels.

3. The method according to claim 1, wherein assigning the levels to the set of circuit parameters of the circuit, further comprises:
receiving a user-defined relationship of circuit parameters and corresponding levels.

4. The method according to claim 1, wherein measuring the values of the circuit parameters during operation of the circuit, further comprises:
generating a reference signal that is independent of process variations, temperature variation, and supply voltage variation; and
measuring the values of the circuit parameters regarding the reference signal.

5. The method according to claim 4, wherein generating the reference signal further comprises:
generating a band-gap reference signal.

6. The method according to claim 1, wherein measuring the values of the circuit parameters during operation of the circuit, further comprises:
converting the measured values to digital values; and
storing the digital values.

7. The method according to claim 1, wherein the feedback relationship is a ratio between a circuit adjustment and a measured circuit parameter.

8. A method for calibrating a circuit performance, comprising:
assigning a level to at least one circuit parameter of a circuit;
measuring a value of the at least one circuit parameter during operation of the circuit;
generating a control signal that corresponds to the value of the at least one measured circuit parameter weighted according to the assigned level; and
adjusting a feedback relationship of a feedback loop of the circuit in a close loop feedback system according to the control signal so as to change the circuit performance.

9. The method according to claim 8, wherein assigning the level to at least one circuit parameter of the circuit, further comprises:
storing a predefined relationship of the circuit parameter and corresponding level.

10. The method according to claim 8, wherein assigning the level to at least one circuit parameter of the circuit, further comprises:
receiving a user-defined relationship of the circuit parameter and corresponding level.

11. The method according to claim 8, wherein measuring the value of the at least one circuit parameter during operation of the circuit, further comprises:
generating a reference signal that is independent of process variations, temperature variation and supply voltage variation; and
measuring the value of the circuit parameter regarding the reference signal.

12. The method according to claim 11, wherein generating the reference signal further comprises:
generating a band-gap reference signal.

13. The method according to claim 8, wherein measuring the value of the at least one circuit parameter during operation of the circuit, further comprises:
converting the measured value to a digital value; and
storing the digital value.

14. The method according to claim 8, wherein the feedback relationship is a ratio between a circuit adjustment and a measured circuit parameter.

15. A system for calibrating a circuit performance, comprising:
a circuit that is configured to have an adjustable parameter that adjusts the circuit performance;
a feedback loop circuit that is configured to have a feedback relationship of an adjustment of the adjustable parameter and a measured circuit parameter; and
a yield enhancement unit that is configured to assign a level to at least one circuit parameter, measure a value of the at least one circuit parameter during operation of the circuit, generate a control signal that corresponds to the measured at least one circuit parameter weighted according to the assigned level, and adjust the feedback relationship according to the control signal to change the circuit performance.

16. The system according to claim 15, further comprising:
a memory unit that is configured to store a predefined relationship of the at least one circuit parameter and the corresponding level, the yield enhancement being configured to assign level to the at least one circuit parameter according to the predefined relationship.

17. The system according to claim 15, further comprising:
an input interface that is configured to receive a user defined relationship of the at least one circuit parameter and the corresponding level, the yield enhancement being configured to assign level to the at least one circuit parameter according to the user defined relationship.

18. The system according to claim 15, wherein the yield enhancement unit further comprises:
at least one monitoring unit that is configured to measure the at least one circuit parameter;
a digitalizing unit that is configured to convert the at least one measured circuit parameter into a digital value;
a memory unit that is configured to store the digital value; and
a controller that is configured to weight the digital value with weight value corresponding to the level to generate the control signal.

19. The system according to claim 15, wherein the yield enhancement unit further comprises:
a bias circuit that is configured to generate a reference signal that is independent of process, temperature, and supply voltage variations, the reference signal being provided to the at least one monitoring unit for reference.

20. The system according to claim 19, wherein the bias circuit further comprises a band-gap reference circuit that generates a band-gap reference signal.

21. An IC chip having an on-chip system for calibrating a circuit performance, comprising:
a circuit that is configured to have an adjustable parameter that adjusts the circuit performance;
a feedback loop circuit that is configured to have a feedback relationship of an adjustment of the adjustable parameter and a measured circuit parameter; and
a yield enhancement unit that is configured to assign a level to at least one circuit parameter, measure a value of the at least one circuit parameter during operation of the circuit, generate a control signal that corresponds to the measured at least one circuit parameter weighted according to the assigned level, and adjust the feedback relationship according to the control signal to change the circuit performance.

22. The IC chip according to claim 21, further comprising:
a memory unit that is configured to store a predefined relationship of the at least one circuit parameter and the corresponding level, the yield enhancement being configured to assign level to the at least one circuit parameter according to the predefined relationship.

23. The IC chip according to claim 21, wherein the yield enhancement unit further comprises:
at least one monitoring unit that is configured to measure the at least one circuit parameter;
a digitalizing unit that is configured to convert the at least one measured circuit parameter into a digital value;
a memory unit that is configured to store the digital value; and
a controller that is configured to weight the digital value with weight value corresponding to the level to generate the control signal.

24. The IC chip according to claim 21, wherein the yield enhancement unit further comprises:
a bias circuit that is configured to generate a reference signal that is independent of process, temperature, and supply voltage variations, the reference signal being provided to the at least one monitoring unit for reference.

25. The IC chip according to claim 24, wherein the bias circuit further comprises a band-gap reference circuit that generates a band-gap reference signal.
